(19) United States
(12) Patent Application Publication
(10) Pub. No.: US 2024/0392215 A1
(43) Pub. Date: Nov. 28, 2024

(54) CLEANING LIQUID, METHOD OF CLEANING SUBSTRATE, AND METHOD OF MANUFACTURING SEMICONDUCTOR ELEMENT

(71) Applicant: Tokyo Ohka Kogyo Co., Ltd., Kawasaki-shi (JP)

(72) Inventors: Kohei Serizawa, Kawasaki-shi (JP); Emi Uchida, Kawasaki-shi (JP)

(21) Appl. No.: 18/667,524

(22) Filed: May 17, 2024

(30) Foreign Application Priority Data
May 25, 2023 (JP) 2023-086304

(51) Int. Cl. C11D 3/20; C11D 3/30

(52) U.S. Cl. CPC C11D 3/2082; C11D 3/30; C11D 2111/22

(57) ABSTRACT

A cleaning liquid that removes an etching residue containing a titanium component, the cleaning liquid including a compound represented by General Formula (a1) and a compound (B) represented by General Formula (b1). In formula (a1), Ra⁰ represents a monovalent organic group containing a hydroxy group or a carboxy group, or a hydrogen atom. In formula (b1), Rb⁰ represents a monovalent organic group or a hydrogen atom

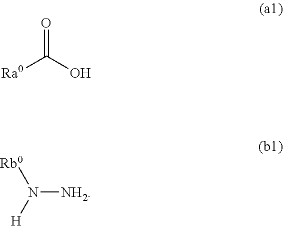

### BACKGROUND OF THE INVENTION

### Field of the Invention

The present invention relates to a cleaning liquid, a method of cleaning a substrate, and a method of manufacturing a semiconductor element.

Priority is claimed on Japanese Patent Application No. 2023-086304, filed May 25, 2023, the content of which is incorporated herein by reference.

### Description of Related Art

In a wiring forming step, for example, a hard mask layer (HM layer) is formed on an interlayer insulating film in which a substrate, a metal wiring layer, and a silicon-based interlayer insulating film are laminated in this order, and the HM layer is etched to form an original form of a wiring pattern. The HM layer contains a titanium component such as titanium nitride (TiN) or titanium oxide (TiOx).

Next, the interlayer insulating film is dry-etched using the etched HM layer as a mask to prepare a wiring pattern similar to that of the mask. Next, the HM layer is removed, and for example, a copper metal film is embedded into the interlayer insulating film having a wiring pattern shape by electroplating.

Inorganic substance-containing residues derived from the metal wiring layer, organic substance-containing residues derived from the interlayer insulating film or the etching gas, and titanium component-containing residues derived from the HM layer are adhered to the dry-etched element (the substrate/the metal wiring layer/the interlayer insulating film/the HM layer).

Dry etching residues are removed by a cleaning treatment in the related art.

A cleaning liquid containing hydroxylamine and alkanolamine as a residue removing agent has been suggested as a cleaning liquid for removing dry etching residues (see, for example, Japanese Unexamined Patent Application, First Publication No. H4-289866).

### SUMMARY OF THE INVENTION

### Technical Problem

The titanium component-containing residues derived from the HM layer adhering to the dry-etched element are residues having high wet resistance and difficult to remove by a cleaning treatment.

In a case where the cleaning liquid described in Japanese Unexamined Patent Application, First Publication No. H4-289866 is used, the cleaning liquid is effective for removing the titanium component-containing residues. However, from the viewpoint of the safety of hydroxylamine, a cleaning liquid that does not contain hydroxylamine is desired.

The present invention has been made in consideration of the above-described circumstances, and an object thereof is to provide a cleaning liquid in which removal properties for titanium component-containing residues adhering to a dry-etched element are satisfactory and the safety is enhanced, and a method of cleaning a substrate and a method of manufacturing a semiconductor element, using this cleaning liquid.

### Solution to Problem

In order to achieve the above-described object, the present invention has employed the following configurations.

According to a first aspect of the present invention, there is provided a cleaning liquid for removing an etching residue containing a titanium component, the cleaning liquid including: a compound (A) represented by General Formula (a1); and a compound (B) represented by General Formula (b1).

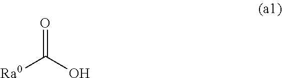

[In the formula, Ra⁰ represents a monovalent organic group containing a hydroxy group or a carboxy group, or a hydrogen atom.]

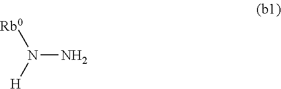

[In the formula, Rb⁰ represents a monovalent organic group or a hydrogen atom.]

According to a second aspect of the present invention, there is provided a method of cleaning a substrate, including: a step (P1) of cleaning a substrate to which an etching residue containing a titanium component is adhered, using the cleaning liquid according to the first aspect.

According to a third aspect of the present invention, there is provided a method of manufacturing a semiconductor element, including: a step (P1) of cleaning a substrate to which an etching residue containing a titanium component is adhered, using the cleaning liquid according to the first aspect.

### Advantageous Effects of Invention

According to the present invention, it is possible to provide a cleaning liquid in which removal properties for titanium component-containing residues adhering to a dry-etched element are satisfactory and the safety is enhanced, and a method of cleaning a substrate and a method of manufacturing a semiconductor element, using this cleaning liquid.

### BRIEF DESCRIPTION OF THE DRAWINGS

FIG. 1 is a cross-sectional view showing an example of a dry-etched element which is a cleaning target.

### DETAILED DESCRIPTION OF THE INVENTION

### (First Aspect: Cleaning Liquid)

A cleaning liquid according to a first aspect of the present invention is a cleaning liquid for removing an etching residue containing a titanium component.

The term “titanium component” here is a compound containing titanium (Ti), and examples thereof include titanium oxide TiOx, titanium nitride TiNx, titanium chloride TiClx, and titanium fluoride TiFx.

The etching residue is particularly a dry etching residue, and examples thereof include a titanium component-containing residue derived from a titanium component-containing layer (such as an adhesive layer, a hard mask layer, or an etching stop layer) that adheres by performing a wiring process. The dry etching residue degrades the yield and electrical characteristics of a semiconductor, and thus is required to be removed before the next step.

The cleaning liquid according to the present aspect is suitable for cleaning a substrate that has been subjected to dry etching, and particularly suitable for cleaning a substrate that has been subjected to dry etching using a titanium component-containing hard mask by a wiring process.

In the cleaning liquid according to the present aspect, “substrate that has been subjected to dry etching”, which is a cleaning target, includes a titanium component-containing layer and the concept thereof includes a single substrate and an element provided with a substrate.

In an embodiment of the cleaning liquid according to the present aspect, there is provided a cleaning liquid containing a compound (A) represented by General Formula (a1) and a compound (B) represented by General Formula (b1).

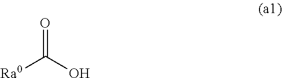

[In the formula, Ra⁰ represents a monovalent organic group containing a hydroxy group or a carboxy group, or a hydrogen atom.]

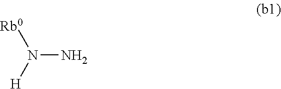

[In the formula, Rb⁰ represents a monovalent organic group or a hydrogen atom.]

### Compound (A)

The cleaning liquid according to the present embodiment contains a compound (A) (hereinafter, also referred to as “component (A)”) represented by General Formula (a1). The effect of removing titanium component-containing residues of the cleaning liquid is increased by using the (A) component in combination with a compound (B) described below.

Examples of the monovalent organic group as Ra⁰ in Formula (a1) include a hydrocarbon group which may have a substituent. The hydrocarbon group may be an aliphatic hydrocarbon group or an aromatic hydrocarbon group, but is preferably an aliphatic hydrocarbon group.

The number of carbon atoms of the aliphatic hydrocarbon group as Ra⁰ is preferably in a range of 1 to 10, more preferably in a range of 1 to 6, and still more preferably in a range of 1 to 4.

The aliphatic hydrocarbon group as Ra⁰ may be a saturated aliphatic hydrocarbon group or an unsaturated aliphatic hydrocarbon group, but is preferably a saturated aliphatic hydrocarbon group.

The aliphatic hydrocarbon group as Ra⁰ may be chain-like or cyclic, but is preferably chain-like.

Among these, a linear or branched chain alkyl group is preferable as the aliphatic hydrocarbon group as Ra⁰.

The linear alkyl group as Ra⁰ is preferably an alkyl group having 1 to 6 carbon atoms, more preferably an alkyl group having 1 to 3 carbon atoms, still more preferably a methyl group or an ethyl group, and particularly preferably a methyl group. It is preferable that the branched chain alkyl group as Ra⁰ has 3 or 4 carbon atoms.

A hydrocarbon group having at least one hydroxy group or carboxy group as a substituent is preferable as the monovalent organic group represented by Ra⁰. The hydrocarbon group may or may not have a substituent other than the hydroxy group or the carboxy group.

As the monovalent organic group represented by Ra⁰, a hydrocarbon group in which one or more hydrogen atoms have been substituted with a hydroxy group or a carboxy group, or a carboxy group is preferable, a hydroxyalkyl group, a carboxyalkyl group, or a carboxy group is more preferable, and a hydroxyalkyl group having 1 to 6 carbon atoms, a carboxyalkyl group having 1 to 6 carbon atoms, or a carboxy group is still more preferable.

The number of hydroxy groups or carboxy groups contained in the monovalent organic group as Ra⁰ is not particularly limited. The number of hydroxy groups or carboxy groups is, for example, preferably in a range of 1 to 10, more preferably in a range of 1 to 6, still more preferably in a range of 1 to 3, and particularly preferably 1. The monovalent organic group as Ra⁰ may have only a hydroxy group or a carboxy group, or may have both a hydroxy group and a carboxy group.

It is preferable that Ra⁰ represents a group having a carbon atom to which a hydroxy group is bonded at the α-position of the carboxy group in Formula (a1). That is, it is preferable that the component (A) is formed such that a hydroxy group is bonded to the carbon atom at the α-position of the carboxy group in Formula (a1). It is preferable that the component (A) is a compound represented by General Formula (a1-1).

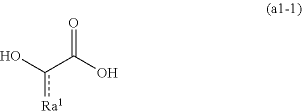

[In the formulae, Ra¹ represents a monovalent organic group, an oxo group, or a hydrogen atom. [symbol]
The formula represents a double bond or a single bond.]

Examples of the monovalent organic group as Ra¹ in Formula (a1-1) include the same groups as those for Ra⁰ in Formula (a1). Examples of the monovalent organic group as Ra¹ include a hydrocarbon group which may have a substituent. Among the examples, an aliphatic hydrocarbon group is preferable, and a saturated aliphatic hydrocarbon group is more preferable. The hydrocarbon group may or may not have a substituent.

Among these, as the aliphatic hydrocarbon group represented by Ra¹, a linear or branched chain alkyl group is preferable, a linear alkyl group having 1 to 6 carbon atoms or a branched chain alkyl group having 3 to 6 carbon atoms is more preferable, a linear alkyl group having 1 to 3 carbon atoms or a branched chain alkyl group having 3 or 4 carbon atoms is still more preferable, and a methyl group is particularly preferable.

Specific examples of the component (A) include a hydroxycarboxylic acid and a dicarboxylic acid. Examples of the hydroxycarboxylic acid include glycolic acid, lactic acid, gluconic acid, taltronic acid, glyceric acid, hydroxybutyric acid (preferably 2-hydroxybutyric acid), malic acid, tartaric acid, citramalic acid, isocitric acid, leucic acid, mevalonic acid, pantoic acid, ricinoleic acid, ricinelaidic acid, cerebronic acid, quinic acid, shikimic acid, gluconic acid, and diglycolic acid. Among these, lactic acid, gluconic acid, and glycolic acid are preferable, and lactic acid and gluconic acid are more preferable.

Examples of the dicarboxylic acid include oxalic acid, malonic acid, succinic acid, and glutaric acid. Among these, oxalic acid is preferable.

Specific examples of the component (A) are shown below.

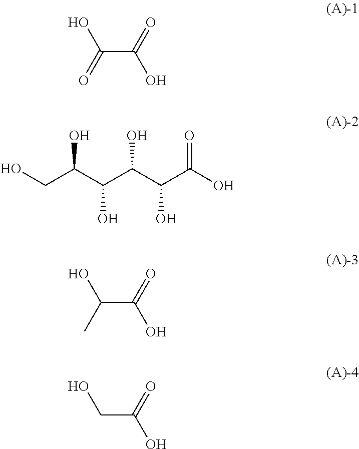

In the cleaning liquid according to the present embodiment, the component (A) may be used alone or a combination of two or more kinds thereof may be used.

In a case where the cleaning liquid contains two or more kinds of the components (A), the content ratio of each component is not limited, but the ratio of the amount of other kinds of the components (A) to the amount of one kind of the component (A) in terms of the mass is preferably in a range of 1 to 5,000, more preferably in a range of 1 to 3,000, still more preferably in a range of 1 to 1,000, and particularly preferably in a range of 1 to 500.

Among the examples, at least one selected from the group consisting of gluconic acid, oxalic acid, lactic acid, and glycolic acid is preferable, and at least one selected from the group consisting of oxalic acid, lactic acid, and glycolic acid is more preferable as the component (A).

The amount of the component (A) in the cleaning liquid of the present embodiment is not particularly limited, but is preferably 0.05% by mass or greater and 30% by mass or less, more preferably 0.1% by mass or greater and 30% by mass or less, and still more preferably 0.5% by mass or greater and 30% by mass or less with respect to the total mass of the cleaning liquid.

In a case where the amount of the component (A) is greater than or equal to the lower limits of the above-described preferable ranges, the removal properties for the titanium component-containing residues after dry etching in the cleaning treatment are further enhanced. Meanwhile, in a case where the amount of the component (A) is less than or equal to the upper limits of the above-described preferable ranges, damage to the metal wiring is further suppressed.

### Compound (B)

The cleaning liquid according to the present embodiment contains a compound (B) (hereinafter, also referred to as “component (B)”) represented by General Formula (b1) in addition to the component (A). In the cleaning liquid, the component (B) acts as a reducing agent. The effect of removing titanium component-containing residues of the cleaning liquid can be increased by using the component (B) in combination with the component (A).

In Formula (b1), examples of the monovalent organic group represented by Rb⁰ include the groups described as the monovalent organic group represented by Ra⁰ in General Formula (a1). The monovalent organic group as Rb⁰ has preferably 1 to 10 carbon atoms, more preferably 1 to 6 carbon atoms, and particularly preferably 1 to 3 carbon atoms. Examples of the monovalent organic group as Rb⁰ include a hydrocarbon group which may have a substituent. The hydrocarbon group may or may not have a substituent. As the hydrocarbon group, an aliphatic hydrocarbon group is preferable, a saturated aliphatic hydrocarbon group is more preferable, and a linear or branched chain alkyl group is still more preferable.

It is preferable that the monovalent organic group as Rb⁰ is a group having a carbon atom to which an oxo group is bonded at the α-position of the hydrazino group in Formula (b1). That is, it is preferable that in the component (B), an oxo group is bonded to the carbon atom at the α-position of the hydrazino group in Formula (b1). Examples of the component (B) include a compound represented by General Formula (b1-1).

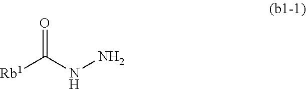

[In the formula, Rb¹ represents a monovalent organic group, a hydrogen atom, an amino group, or a hydrazino group.]

In Formula (b1-1), examples of the monovalent organic group represented by Rb¹ include the groups described as the monovalent organic group represented by Ra⁰ in Formula (a1). The monovalent organic group as Rb⁰ has preferably 1 to 10 carbon atoms, more preferably 1 to 6 carbon atoms, and particularly preferably 1 to 3 carbon atoms. Examples of the monovalent organic group as Rb¹ include a hydrocarbon group which may have a substituent. The hydrocarbon group may or may not have a substituent. As the hydrocarbon group, an aliphatic hydrocarbon group is preferable, a saturated aliphatic hydrocarbon group is more preferable, and a linear or branched chain alkyl group is still more preferable.

It is preferable that Rb¹ represents a hydrogen atom, an amino group, or a hydrazino group.

A compound represented by General Formula (b1-1-1) is preferable as the compound represented by General Formula (b1-1).

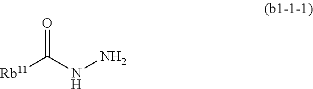

[In the formula, Rb¹¹ represents a hydrocarbon group which may have a substituent that substitutes a hydrogen atom, a hydrogen atom, an amino group, or a hydrazino group.]

In Formula (b1-1-1), examples of the hydrocarbon group which may have a substituent as Rb¹¹ include the same groups described as the hydrocarbon group which may have a substituent as Ra⁰ in Formula (a1). As the hydrocarbon group as Rb¹¹, an aliphatic hydrocarbon group is preferable, a saturated aliphatic hydrocarbon group is more preferable, and a linear or branched chain alkyl group is still more preferable. The hydrocarbon group as Rb¹¹ may or may not have a substituent. The substituent that the hydrocarbon group as Rb¹¹ may have is a substituent that substitutes a hydrogen atom. Examples of the substituent include a hydroxy group, an amino group, a carboxy group, and a hydrazino group. The number of carbon atoms of the hydrocarbon group as Rb¹¹ is preferably in a range of 1 to 10, more preferably in a range of 1 to 6, and still more preferably in a range of 1 to 3. Examples of the hydrocarbon group which may have a substituent as Rb¹¹ include a group represented by General Formula (Rb-11).

It is preferable that Rb¹¹ represents a hydrogen atom, an amino group, or a hydrazino group.

Specific examples of the component (B) are shown below.

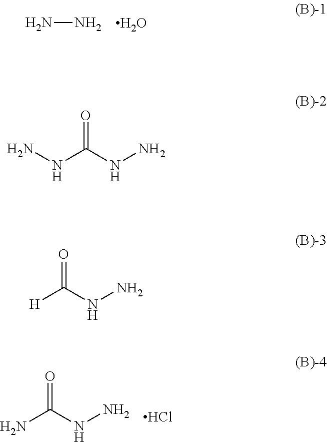

In the cleaning liquid according to the present embodiment, the component (B) may be used alone or a combination of two or more kinds thereof may be used.

Among the examples, at least one selected from the group consisting of hydrazine, carbohydrazide, formic acid hydrazide, and semicarbazide is preferable as the component (B). These compounds may be hydrates or may be in the form of salts. Examples of the hydrate include a monohydrate and a dihydrate. Examples of the form of salts include a hydrochloride and a sulfate. For example, the hydrazine may be a hydrazine monohydrate. The semicarbazide may be a semicarbazide hydrochloride. A component that is not hydrazinocarboxylic acid ester is preferable as the component (B).

The amount of the component (B) in the cleaning liquid according to the present embodiment is not particularly limited, but is preferably 0.05% by mass or greater and 30% by mass or less, more preferably 0.1% by mass or greater and 30% by mass or less, and still more preferably 0.5% by mass or greater and 30% by mass or less with respect to the total mass of the cleaning liquid.

In a case where the amount of the component (B) is greater than or equal to the lower limits of the above-described preferable ranges, the removal properties for the titanium component-containing residues after dry etching in the cleaning treatment are further enhanced. Meanwhile, in a case where the amount of the component (B) is less than or equal to the upper limits of the above-described preferable ranges, damage to the metal wiring is further suppressed.

The mass ratio of the amount of the component (A) to the amount of the component (B) (component (A)/component (B)) is preferably in a range of 0.0001 to 200, more preferably in a range of 0.001 to 150, still more preferably in a range of 0.01 to 50, and particularly preferably in a range of 0.05 to 30.

In a case where the mass ratio of the amount of the component (A) to the amount of the component (B) is in the above-described preferable ranges, the removal properties for the titanium component-containing residues after dry etching in the cleaning treatment are further enhanced.

### Solvent

It is preferable that the cleaning liquid of the present embodiment contains water as a solvent.

Water may contain a trace amount of components that are unavoidably mixed. As water that may be used in the cleaning liquid of the present embodiment, water subjected to a purification treatment, such as distilled water, ion exchange water, or ultrapure water is preferable, and ultrapure water typically used in the manufacture of a semiconductor is more preferable.

Water can be blended into the cleaning liquid according to the present embodiment such that the total amount of the component (A), the component (B), and the following optional components blended as necessary reaches 100% by mass, that is, the amount of water is the remaining amount. The amount of water in the cleaning liquid according to the present embodiment is, for example, 20% by mass or greater and 98% by mass or less, preferably 30% by mass or greater and 95% by mass or less, and more preferably 40% by mass or greater and 95% by mass or less. In a case where the amount of water is in the above-described preferable ranges, the component (A) and the component (B) are likely to be balanced.

The cleaning liquid according to the present embodiment may contain the following organic solvent in addition to water as a solvent.

### Optional Components

The cleaning liquid according to the present embodiment may contain optional components in addition to the component (A), the component (B), and the solvent. Examples of the optional components include a pH adjusting agent, an anticorrosive agent, a buffer, an organic solvent, a surfactant, and a pH adjusting agent.

### pH Adjusting Agent

The cleaning liquid according to the present embodiment may contain a pH adjusting agent in order to adjust the pH of the cleaning liquid. The pH adjusting agent may be a base or an acid.

### Base

It is preferable that the cleaning liquid according to the present embodiment further contains a base (excluding a component corresponding to the component (B)) in addition to the component (B). In a case where the cleaning liquid according to the present embodiment contains a base, the pH of the cleaning liquid can be adjusted to be high, and thus the effect of removing the titanium component-containing residues is likely to be exhibited.

Examples of the base include those selected from the group consisting of amines and ammonium compounds.

Examples of the amine as the base include ammonia (NH₃), a primary monoamine, a secondary monoamine, a tertiary monoamine, alkanolamine, a secondary cyclic amine, a tertiary cyclic amine, a quaternary cyclic amine, a diamine, a polyamine.

Examples of the primary monoamine include alkylamines such as methylamine, ethylamine, propylamine, n-butylamine, isopropylamine, and tert-butylamine; cycloalkylamines such as cyclopentylamine, cyclohexylamine, and cyclohexanemethylamine; and alkoxyamines such as methoxyethylamine, methoxypropylamine, methoxybutylamine, ethoxypropylamine, and propoxypropylamine.

Examples of the secondary monoamine include alkylamines such as dimethylamine, diethylamine, methylethylamine, dipropylamine, diisopropylamine, dibutylamine, diisobutylamine, and butylmethylamine; cycloalkylamines such as N,N-dicyclohexylamine and N-cyclopentylcyclohexanamine; and alkoxyamines such as methoxy(methylamine) and N-(2-methoxyethyl)ethylamine.

Examples of the tertiary monoamine include alkylamines such as trimethylamine, triethylamine, tripropylamine, tributylamine, triisobutylamine, dimethylethylamine, dimethylpropylamine, allyldiethylamine, dimethyl-n-butylamine, and diethylisopropylamine; and cycloalkylamines such as tricyclopentylamine and tricyclohexylamine.

Examples of the alkanolamine include monoethanolamine, 2-aminoethanol, 1-amino-2-propanol, 2-amino-1-propanol, 4-amino-1-butanolamine, 2-amino-2-methyl-1-propanol, 2-(2-aminoethoxy)ethanol, N-methylethanolamine, N-ethylethanolamine, N-methylpropanolamine, diethanolamine, diisopropanolamine, 2-[(hydroxymethyl)amino]ethanol, 4-methylaminobutanol, 3-piperidinemethanol, 4-piperidinemethanol, 2-piperidineethanol, 4-piperidineethanol, N,N-dimethylethanolamine, N,N-dimethylpropanolamine, N,N-diethylethanolamine, N-ethyldiethanolamine, N-methyldiethanolamine, triethanolamine, and triisopropanolamine.

Examples of the secondary cyclic amines include piperidines (compounds having a piperidine skeleton), pyrrolidines (compounds having a pyrrolidine skeleton), and morpholines (compounds having a morpholine skeleton). Examples of the piperidines which are secondary cyclic amines include piperidine, 2-pipecoline, 3-pipecoline, 4-pipecoline, 2,6-dimethylpiperidine, and 3,5-dimethylpiperidine. Examples of the pyrrolidines include pyrrolidine, 2-methylpyrrolidine, and 3-methylpyrrolidine. Examples of the morpholines include morpholine, 2-methylmorpholine, and 3-methylmorpholine.

Examples of the tertiary cyclic amines include piperidines, pyrrolidines, and morpholines. Examples of the piperidines include N-methylpiperidine. Examples of the pyrrolidines include N-methylpyrrolidine. Examples of the morpholines include N-methylmorpholine.

Examples of the quaternary cyclic amines include fluorides, chlorides, bromides, iodides, sulfates, hydrogensulfates, acetates, and such of piperidines, pyrrolidines, morpholines, and such.

The diamine may be any of a primary diamine, a secondary diamine, or a tertiary diamine. Examples of the primary diamine include 2-(2-aminoethylamino)ethanol, ethylenediamine, butane-1,4-diamine, 1,3-propanediamine, 1,6-hexanediamine, and pentane-1,5-diamine. Examples of the secondary diamine include 2-methylpiperazine, 2,3-dimethylpiperazine, 2,5-dimethylpiperazine, N,N′-dimethylethanediamine, N,N′-dimethylpropanediamine, N,N′-diethylethylenediamine, N,N′-diethylpropanediamine, and N,N′-diisopropylethylenediamine. Examples of the tertiary diamine include 4-dimethylaminopyridine, N,N,N′,N′-tetramethylethylenediamine, N,N,N′,N′-tetraethylethylenediamine, N,N,N′,N′-tetramethyl-1,3-diaminopropane, N,N,N′,N′-tetramethyl-1,3-diaminobutane, N,N,N′,N′-tetramethyl-1,4-diaminobutane, N,N,N′,N′-tetramethylphenylenediamine, and 1,2-dipiperidinoethane.

The polyamine is a compound containing three or more amino groups, and a triamine is preferable. The polyamine may contain any of a primary amino group, a secondary amino group, or a tertiary amino group. Examples of the polyamine include spermine, spermidine, 3,3′-iminobis(propylamine), N,N-bis(3-aminopropyl)methylamine, N,N-bis(3-aminopropyl)butylamine, N-(3-aminopropyl)-N-dodecylpropane-1,3-diamine, diethylenetriamine, N,N,N′,N″,N″-pentamethyldiethylenetriamine, N,N,N′,N″,N″-pentamethyldipropylenetriamine, tris[2-(dimethylamino)ethyl]amine, 2-aminomethylpyrimidine, 1,4-bis(3-aminopropyl)piperazine, 1-amino-4-cyclopentylpiperazine, and 1-(2-pyridyl)piperazine.

Examples of the ammonium compound as the base include a hydroxide of a quaternary amine and a quaternary ammonium salt other than a hydroxide.

Tetraalkylammonium hydroxide is preferable as the hydroxide of a quaternary amine, and examples thereof include tetramethylammonium hydroxide, tetraethylammonium hydroxide, tetrapropylammonium hydroxide, dimethylbis(2-hydroxyethyl)ammonium hydroxide, tetrabutylammonium hydroxide, tetrapentylammonium hydroxide, tris(2-hydroxyethyl)methylammonium hydroxide, choline, dimethyldiethylammonium hydroxide, tetraethanolammonium hydroxide, benzyltrimethylammonium hydroxide, benzyltriethylammonium hydroxide, and benzyltributylammonium hydroxide.

Examples of the quaternary ammonium salt other than the hydroxide include a fluoride, a chloride, a bromide, an iodide, a sulfate, a hydrogensulfate, and an acetate of quaternary ammonium. Specific examples of the quaternary ammonium salt include tetraethylammonium chloride, tetramethylammonium chloride, tetrapropylammonium chloride, tetrabutylammonium chloride, tetrapentylammonium chloride, tetraethylammonium bromide, tetramethylammonium bromide, tetrapropylammonium bromide, tetrabutylammonium bromide, tetrapentylammonium bromide, tetraethylammonium fluoride, tetramethylammonium fluoride, tetrapropylammonium fluoride, tetrabutylammonium fluoride, tetrapentylammonium fluoride, tetraethylammonium iodide, tetramethylammonium iodide, tetrapropylammonium iodide, tetrabutylammonium iodide, tetrapentylammonium iodide, tetraethylammonium hydrogensulfate, tetramethylammonium hydrogensulfate, tetrapropylammonium hydrogensulfate, and tetrabutylammonium hydrogensulfate.

In the cleaning liquid according to the present embodiment, the base may be used alone or a combination of two or more kinds thereof may be used.

Among the bases, it is preferable to use at least one selected from the group consisting of ammonia, alkanolamine, tetraalkylammonium hydroxide, a triamine, and a diamine and more preferable to use at least one selected from the group consisting of ammonia, monoethanolamine, tetramethylammonium hydroxide, tetraethylammonium hydroxide, diethylenetriamine, and 2-(2-aminoethylamino)ethanol.

Among these, from the viewpoint of the removal properties for the titanium component-containing residues, it is preferable to use at least one selected from the group consisting of ammonia, alkanolamine, and tetraalkylammonium hydroxide, more preferable to use at least one selected from the group consisting of ammonia, monoethanolamine, tetramethylammonium hydroxide, and tetraethylammonium hydroxide, and still more preferable to use at least one selected from the group consisting of ammonia, tetramethylammonium hydroxide, and tetraethylammonium hydroxide, as the base.

In a case where the cleaning liquid according to the present embodiment contains a base other than the component (B), the amount of the base may be, for example, 0.001% by mass or greater and 30% by mass or less, 0.01% by mass or greater and 25% by mass or less, or 0.5% by mass or greater and 20% by mass or less with respect to the total mass of the cleaning liquid.

In a case where the amount of the base is greater than or equal to the lower limits of the above-described ranges, the removal properties for the titanium component-containing residues in the cleaning treatment are further enhanced. Meanwhile, in a case where the amount of the base is less than or equal to the upper limits of the above-described ranges, the balance between the component (A) and the component (B) is likely to be achieved.

The cleaning liquid according to the present embodiment may not contain a base other than the component (B), and may not contain one or more of the compounds described as the specific examples of the base other than the component (B).

### Acid

The cleaning liquid according to the present embodiment may further contain an acid component (excluding a component corresponding to the component (A)) in addition to the component (A). The acid may be an inorganic acid (such as hydrochloric acid, sulfuric acid, carbonic acid, phosphoric acid, or nitric acid) or an organic acid. Examples of the organic acid include a carboxylic acid. Examples of the carboxylic acid include those selected from the group consisting of fatty acids and amino acids.

Examples of the fatty acid include fatty acids having 1 to 22 carbon atoms, and examples thereof include formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, eicosapentaenoic acid, and docosahexaenoic acid.

Examples of the amino acid include glycine, alanine, arginine, asparagine, aspartic acid, cysteine, glutamine, glutamic acid, histidine, isoleucine, leucine, lysine, methionine, phenylalanine, proline, serine, threonine, tryptophan, tyrosine, and valine.

In the cleaning liquid according to the present embodiment, the acid other than the component (A) may be used alone or a combination of two or more kinds thereof may be used.

In a case where the cleaning liquid according to the present embodiment contains an acid other than the component (A), the amount of the acid in the cleaning liquid may be 0.0001% by mass or greater and 10% by mass or less, 0.001% by mass or greater and 5% by mass or less, or 0.01% by mass or greater and 3% by mass or less with respect to the total mass of the cleaning liquid.

The cleaning liquid according to the present embodiment may not contain an acid other than the component (A), and may not contain one or more of the compounds described as the specific examples of the acid other than the component (A).

### Anticorrosive Agent

The cleaning liquid of the present embodiment may contain an anticorrosive agent.

Examples of the anticorrosive agent include compounds having a nitrogen-containing heterocyclic ring such as a triazole ring, an imidazole ring, a pyridine ring, a phenanthroline ring, a tetrazole ring, a pyrazole ring, a pyrimidine ring, or a purine ring.

The cleaning liquid according to the present embodiment may not contain the anticorrosive agent, and may not contain one or more of the compounds described as the specific examples of the anticorrosive agent.

### Buffer

The cleaning liquid according to the present embodiment may contain a buffer. The buffer is a compound having an action of suppressing a change in the pH of a cleaning liquid.

The buffer is not particularly limited as long as the buffer is a compound having a pH buffering capacity. As the buffer, for example, a compound with a pKa of 6 to 11 can be used.

Examples of the buffer include a Good's buffer. Example of the Good's buffer include 2-cyclohexylaminoethanesulfonic acid (CHES), 3-cyclohexylaminopropanesulfonic acid (CAPS), N-tris(hydroxymethyl)methyl-3-aminopropanesulfonic acid (TAPS), 4-(cyclohexylamino)-1-butanesulfonic acid (CABS), tricine, bicine, 2-morpholinoethanesulfonic acid monohydrate (MES), bis(2-hydroxyethyl)aminotris(hydroxymethyl)methane (Bis-Tris), piperazine-1,4-bis(2-ethanesulfonic acid) (PIPES), N-(2-acetamido)-2-aminoethanesulfonic acid (ACES), 2-hydroxy-3-morpholinopropanesulfonic acid (MOPSO), N,N-bis(2-hydroxyethyl)-2-aminoethanesulfonic acid (BES), 3-morpholinopropanesulfonic acid (MOPS), N-tris(hydroxymethyl)methyl-2-aminoethanesulfonic acid (TES), 2-[4-(2-hydroxyethyl)-1-piperazinyl]ethanesulfonic acid (HEPES), 3-[N-tris(hydroxymethyl)methylamino]-2-hydroxypropanesulfonic acid (TAPSO), piperazine-1,4-bis(2-hydroxypropanesulfonic acid) (POPSO), 4-(2-hydroxyethyl)piperazine-1-(2-hydroxypropane-3-sulfonic acid) (HEPSO), and 4-(2-hydroxyethyl)-1-piperazinepropanesulfonic acid (EPPS).

The cleaning liquid of the present embodiment may not contain the buffer, and may not contain one or more of the compounds described as specific examples of the buffer.

### Organic Solvent

The cleaning liquid according to the present embodiment may contain an organic solvent within a range where the effects of the present invention are not impaired. A water-soluble organic solvent is preferable as the organic solvent. In a case where the cleaning liquid contains an organic solvent, organic residues such as polymers are easily removed.

Examples of the water-soluble organic solvent include alcohols such as isopropanol, ethanol, ethylene glycol, propylene glycol, glycerin, 1,3-propanediol, 1,3-butanediol, 1,4-butanediol, diethylene glycol, dipropylene glycol, furfuryl alcohol, 2-methyl-2,4-pentanediol, and 3-methoxy-3-methyl-1-butanol; dimethyl sulfoxide; ethers such as ethylene glycol dimethyl ether, diethylene glycol dimethyl ether, triethylene glycol dimethyl ether, tetraethylene glycol dimethyl ether, and propylene glycol dimethyl ether; and morpholines such as N-methylmorpholine N-oxide.

The organic solvent may be used alone or a combination of two or more kinds thereof may be used.

Among the organic solvents, it is preferable to use at least one selected from the group consisting of alcohols, ethers, and morpholines, more preferable to use at least one selected from the group consisting of alcohols, and still more preferable to use 2-methyl-2,4-pentanediol.

In a case where the cleaning liquid according to the present embodiment contains an organic solvent, the amount of the organic solvent is preferably in a range of 0.01% to 90% by mass, more preferably in a range of 0.05% to 75% by mass, still more preferably in a range 0.1% to 50% by mass, and particularly preferably in a range of 0.1% to 25% by mass with respect to the total mass of the cleaning liquid.

The cleaning liquid according to the present embodiment may not contain the organic solvent or the water-soluble organic solvent, and may not contain one or more of the compounds described as specific examples of the water-soluble organic solvent.

In a case where a mixed solvent of water and an organic solvent is used as the solvent of the cleaning liquid, the amount of the organic solvent is preferably in a range of 10% to 90% by mass, more preferably in a range of 20% to 80% by mass, and still more preferably in a range of 25% to 75% by mass with respect to the total mass of the cleaning liquid.

### Surfactant

The cleaning liquid of the present embodiment may contain a surfactant, for example, for the purpose of adjusting the wettability of the cleaning liquid to a substrate. Examples of the surfactant include a nonionic surfactant, an anionic surfactant, a cationic surfactant, and an amphoteric surfactant.

Examples of the nonionic surfactant include polyalkylene oxide alkylphenyl ether-based surfactants, polyalkylene oxide alkyl ether-based surfactants, block polymer-based surfactants consisting of polyethylene oxide and polypropylene oxide, polyoxyalkylene distyrenated phenyl ether-based surfactants, polyalkylene tribenzylphenyl ether-based surfactants, and acetylene polyalkylene oxide-based surfactants.

Examples of the anionic surfactant include alkylsulfonic acids, alkylbenzenesulfonic acids, alkylnaphthalenesulfonic acids, alkyldiphenyl ether sulfonic acids, fatty acid amidosulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. Examples of “salts” include ammonium salts, sodium salts, potassium salts, and tetramethylammonium salts.

Examples of cationic surfactant include alkylpyridium-based surfactants and quaternary ammonium salt-based surfactants.

Examples of the amphoteric surfactant include betaine type surfactants, amino acid type surfactants, imidazoline type surfactants, and amine oxide type surfactants.

These surfactants are generally commercially available. The surfactant may be used alone or a combination of two or more kinds thereof may be used.

In a case where the cleaning liquid of the present embodiment contains the surfactant, the amount of the surfactant is not particularly limited, but is, for example, preferably in a range of 0.0001% by mass to 5% by mass, more preferably in a range of 0.0002% by mass to 3% by mass, still more preferably in a range of 0.002% by mass to 1% by mass, and particularly preferably in a range of 0.002% by mass to 0.2% by mass with respect to the total mass of the cleaning liquid.

The cleaning liquid according to the present embodiment may not contain one or more selected from the group consisting of a nonionic surfactant, an anionic surfactant, a cationic surfactant, and an amphoteric surfactant, and may not contain one or more of the compounds described as the surfactant. The cleaning liquid of the present embodiment may not contain the surfactant.

### Impurities and the Like

The cleaning liquid of the present embodiment may include metal impurities including metal atoms such as a Fe atom, a Cr atom, an Ni atom, a Zn atom, a Ca atom, and a Pb atom.

The total amount of the metal atoms in the cleaning liquid of the present embodiment is preferably 100 ppt by mass or less with respect to the total mass of the cleaning liquid. The lower limit of the total amount of the metal atoms is preferably as low as possible, but may be, for example, 0.001 ppt by mass or greater. The total amount of the metal atoms may be, for example, 0.001 ppt by mass to 100 ppt by mass. By setting the total amount of the metal atoms to less than or equal to the preferable upper limit, the defect suppressing properties and the residue suppressing properties of the cleaning liquid are improved. It is considered that in a case where the total amount of the metal atoms is set to greater than or equal to the preferable lower limit, the metal atoms are less likely to be released in the system and less likely to adversely affect the production yield of the entire object to be cleaned.

The amount of the metal impurities can be adjusted, for example, by a purification treatment such as filtering. A purification treatment such as filtering may be performed on a part or all of the raw materials before preparing the cleaning liquid, or may be performed after preparing the cleaning liquid.

The cleaning liquid of the present embodiment may include, for example, organic substance-derived impurities (organic impurities). The total amount of the organic impurities in the cleaning liquid of the present embodiment is preferably 5,000 ppm by mass or less. The lower limit of the amount of the organic impurities is preferably as low as possible, and the lower limit may be, for example, greater than or equal to 0.1 ppm by mass. The total amount of the organic impurities is, for example, 0.1 ppm by mass to 5,000 ppm by mass.

The cleaning liquid of the present embodiment may include, for example, objects to be counted having a size that can be counted by a light scattering type in-liquid particle counter. The size of the object to be counted is, for example, 0.04 μm or greater. The number of the objects to be counted in the cleaning liquid of the present embodiment is, for example, 1,000 or less per mL of the cleaning liquid, and the lower limit is, for example, 1 or greater. It is considered that in a case where the number of the objects to be counted in the cleaning liquid is within the range, the metal corrosion suppressing effect of the cleaning liquid is improved.

The organic impurities and/or the objects to be counted may be added to the cleaning liquid, or may be unavoidably mixed in the cleaning liquid during a step of producing the cleaning liquid. Examples of the cases where organic impurities are unavoidably mixed in the step of producing the cleaning liquid include a case where raw materials (for example, an organic solvent) used in the production of the cleaning liquid contain organic impurities and a case where organic impurities are mixed (for example, contamination) from the external environment in the step of producing the cleaning liquid, but the examples are not limited thereto.

In a case where the objects to be counted are added to the cleaning liquid, the existence ratio may be adjusted for each specific size in consideration of the surface roughness and the like of a cleaning target.

### pH of Cleaning Liquid

The pH of the cleaning liquid according to the present embodiment is preferably 0.5 or greater and 14 or less, more preferably 3 or greater and 12 or less, still more preferably 5 or greater and 12 or less, even still more preferably 7 or greater and 12 or less, and particularly preferably 8 or greater and 10 or less.

In a case where the pH of the cleaning liquid is within the above-described ranges, the removal properties for titanium component-containing residues in the cleaning treatment are enhanced.

The pH of the cleaning liquid is a value measured at 23° C. with a pH meter under a condition of a normal pressure (1 atm).

Suitable examples of the cleaning liquid according to the present embodiment include the following embodiment (1-1).

Embodiment (1-1): a cleaning liquid containing the component (A), the component (B), the base (excluding a base corresponding to the component (B)), and water

### In Regard to Embodiment (1-1)

The cleaning liquid according to the embodiment (1-1) contains a compound (A), a compound (B), a base, and water as the remaining amount, and may contain optional components as necessary.

It is preferable to use at least one selected from the group consisting of gluconic acid, oxalic acid, lactic acid, and glycolic acid and more preferable to use at least one selected from the group consisting of oxalic acid, lactic acid, and glycolic acid, as the compound (A).

It is preferable to use at least one selected from the group consisting of hydrazine, carbohydrazide, formic acid hydrazide, and semicarbazide as the compound (B).

It is preferable to use, as the base, at least one selected from the group consisting of ammonia, alkanolamine, and tetraalkylammonium hydroxide, more preferable to use at least one selected from the group consisting of ammonia, monoethanolamine, tetramethylammonium hydroxide, and tetraethylammonium hydroxide, and still more preferable to use at least one selected from the group consisting of ammonia, tetramethylammonium hydroxide, and tetraethylammonium hydroxide.

It is preferable to use only water or a mixed solvent of water and an organic solvent as the solvent.

The amount of the compound (A) in the cleaning liquid according to the embodiment (1-1) is preferably 0.05% by mass or greater and 30% by mass or less, more preferably 0.1% by mass or greater and 30% by mass or less, and still more preferably 0.5% by mass or greater and 30% by mass or less with respect to the total mass of the cleaning liquid.

The amount of the compound (B) in the cleaning liquid according to the embodiment (1-1) is preferably 0.05% by mass or greater and 30% by mass or less, more preferably 0.1% by mass or greater and 30% by mass or less, and still more preferably 0.5% by mass or greater and 30% by mass or less with respect to the total mass of the cleaning liquid.

The amount of the base in the cleaning liquid according to the embodiment (1-1) may be 0.001% by mass or greater and 30% by mass or less, 0.01% by mass or greater and 25% by mass or less, or 0.5% by mass or greater and 20% by mass or less with respect to the total mass of the cleaning liquid.

The pH of the cleaning liquid according to the embodiment (1-1) which is measured at 23° C. is preferably 0.5 or greater and 14 or less, more preferably 3 or greater and 12 or less, still more preferably 5 or greater and 12 or less, even still more preferably 7 or greater and 12 or less, and particularly preferably 8 or greater and 10 or less.

A method of storing the cleaning liquid of the present embodiment is not particularly limited, and storage containers known in the related art can be used. In order to ensure the stability of the cleaning liquid, a void ratio in a container in a case of storing the cleaning liquid in the container and/or a type of gas filling the voids may be appropriately set. For example, the void ratio in the storage container may be approximately in a range of 0.01% to 30% by volume.

As described above, the cleaning liquid according to the present embodiment contains the compound (A) represented by General Formula (a1) and the compound (B) represented by General Formula (b1). According to the cleaning liquid, the removal properties for the titanium component-containing residues adhering to a dry-etched element are satisfactory.

The reason why the removal properties for the titanium component-containing residues are improved by the combination of the compound (A) and the compound (B) is not clear, but is assumed as follows.

The surface of the titanium component-containing residues is reduced by the compound (B), and thus the compound (A) is likely to be chelated. It is assumed that since the compound (A) chelates the surface of the titanium component-containing residue, the titanium component-containing residues are likely to be removed.

The cleaning liquid according to the present embodiment can exhibit cleaning properties with respect to the titanium component-containing residues, similar to the cleaning properties of a general-purpose cleaning liquid containing hydroxylamine in the related art, by using a combination of the compound (A) and the compound (B). Since the cleaning liquid according to the present embodiment is not required to contain hydroxylamine, the safety of the cleaning liquid is further enhanced than the safety of a cleaning liquid containing hydroxylamine in the related art.

Further, the hydroxylamine is an explosive compound, and is a substance that belongs to Class 5 hazardous materials (self-reactive substance) in the Fire Service Act of Japan and is designated as a deleterious substance by the Poisonous and Deleterious Substances Control Act of Japan.

It is preferable that the cleaning liquid according to the present embodiment contains no hydroxylamine.

The cleaning liquid according to the present embodiment may be a cleaning liquid that does not contain at least one selected from the group consisting of hydrazinocarboxylic acid ester and alkanolamine.

### Second Aspect: Method of Cleaning Substrate

A method of cleaning a substrate according to a second aspect of the present invention includes a step (P1) of cleaning a substrate to which etching residues containing a titanium component are adhered, using the cleaning liquid according to the first aspect.

In the cleaning method according to the present aspect, the concept of the substrate to which etching residues, serving as a cleaning target, containing a titanium component (titanium component-containing residues) are adhered includes a single substrate and an element provided with a substrate.

The element may be an element after a metal wiring layer is subjected to dry etching by, for example, a semi-damascene process. Further, the element may be an element in which a metal wiring layer is exposed after a Si-containing layer (for example, a Si-containing interlayer insulating film) is subjected to dry etching by a wiring process. Further, the element may be a substrate in which a metal wiring layer is exposed after a CMP step in a wiring process.

Suitable examples of the metal wiring layer include a layer containing at least one metal selected from the group consisting of molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

Hereinafter, an embodiment of the method of cleaning a substrate according to the present aspect will be described with reference to the accompanying drawing.

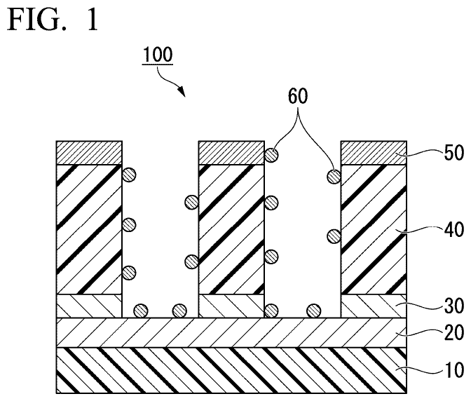

FIG. 1 shows an example of a dry-etched element (the substrate/the metal wiring layer/the interlayer insulating film/the HM layer) as an element including a substrate which is a cleaning target.

An element 100 shown in FIG. 1 is formed such that a substrate 10, a metal wiring layer 20, an etching stop layer 30, and an interlayer insulating film 40 are laminated in this order and a hard mask layer (HM layer) 50 is formed on the interlayer insulating film 40.

The element 100 is an element that has been subjected to dry etching by the wiring process, that is, an element in a state after the interlayer insulating film 40 is dry-etched using the HM layer 50 on which an original form of a wiring pattern has been formed by dry etching, as a mask. Dry etching residues 60 adhere to the side surfaces of the HM layer 50 and the interlayer insulating film 40.

In space portions between the interlayer insulating films 40 having a wiring pattern shape, the metal wiring layer 20 is exposed, and the dry etching residues 60 are also adhered to the exposed metal wiring layer 20.

The substrate 10 is formed of a material such as silicon, amorphous silicon, or glass.

The metal wiring layer 20 is a wiring layer formed of metals such as molybdenum, tungsten, ruthenium, copper, iron, nickel, aluminum, lead, zinc, tin, tantalum, magnesium, cobalt, bismuth, cadmium, titanium, zirconium, antimony, manganese, beryllium, chromium, germanium, vanadium, gallium, hafnium, indium, niobium, rhenium, and thallium.

The interlayer insulating film 40 is formed of a silicon-based material such as SiO₂, SiN, SiOC, SiOF, SiOCH, SiCN, SiOF, or SiOH.

The HM layer 50 is a titanium component-containing layer formed of a titanium component such as titanium nitride (TiN) or titanium oxide (TiOx).

The dry etching residues 60 are mainly titanium component-containing residues containing a titanium component derived from the HM layer 50.

### Cleaning Step (P1)

The present step (P1) is a step of cleaning the element 100 after the element is dry-etched by the wiring process using the cleaning liquid according to the first aspect.

The cleaning method is not particularly limited, and a known cleaning method can be used.

In a case where the cleaning liquid is brought into contact with the element 100 which is a cleaning target, the cleaning liquid may be diluted 2 to 2,000 times to obtain a diluted liquid, and an operation of cleaning the element 100 using the diluted liquid may be performed.

Examples of the cleaning operation include a method of continuously coating the element 100 rotating at a constant speed with the cleaning liquid (rotation coating method), a method of dipping the element 100 in the cleaning liquid for a certain time (dip method), and a method of spraying the cleaning liquid to the surface of the element 100 (spraying method).

The temperature at which the cleaning treatment is performed is not particularly limited. The cleaning treatment is performed under a temperature condition of preferably 10° C. to 80° C., and the temperature may be in a range of 20° C. to 75° C. or 40° C. to 70° C.

The removal properties for the etching residues are improved by increasing the temperature of the cleaning liquid, but the temperature of the cleaning liquid can be appropriately selected in consideration of suppression of a change in the composition of the cleaning liquid, workability, the safety, the cost, and the like.

As the cleaning time, a time sufficient for removing etching residues, impurities, and the like adhering to the surface of the element 100 can be appropriately selected. The cleaning time is, for example, in a range of 10 seconds to 30 minutes, and may be in a range of 20 seconds to 15 minutes, in a range of 30 seconds to 10 minutes, or in a range of 30 seconds to 5 minutes.

According to the cleaning method of the present embodiment described above, since the element 100 to which the dry etching residues 60 are adhered is cleaned by using the cleaning liquid according to the first aspect, the titanium component-containing residues derived from the HM layer 50 can be satisfactorily cleaned and removed while damage to the metal wiring layer 20 is suppressed. Further, according to the cleaning method of the present embodiment, damage to the interlayer insulating film 40 can also be suppressed.

Further, since the cleaning liquid is not required to contain hydroxylamine by using a combination of the compound (A) and the compound (B), the substrate can be more safely cleaned with the cleaning liquid as compared with a case where a cleaning liquid containing hydroxylamine in the related art is used.

In the method of cleaning a substrate according to the embodiment described above, the case where the HM layer 50 in FIG. 1 is a titanium component-containing layer has been described, but the method of cleaning a substrate according to the second aspect of the present invention is not limited to the embodiment, and for example, the etching stop layer 30 may be a titanium component-containing layer or an adhesive layer (not shown) formed by bonding each layer constituting the element 100 may be a titanium component-containing layer. That is, the method of cleaning a substrate according to the present aspect is a method particularly useful in a case where a substrate serving as a cleaning target is a substrate that includes a titanium component-containing layer and has been subjected to dry etching.

### (Third Aspect: Method of Manufacturing Semiconductor Element)

A method of manufacturing a semiconductor element according to a third aspect of the present invention is a manufacturing method including a step (P1) of cleaning a substrate to which etching residues including a titanium component are adhered, using the cleaning liquid according to the first aspect.

A manufacturing method including the step (P1) and optional steps is an exemplary example of an embodiment of the method of manufacturing a semiconductor element.

In the manufacturing method according to the present embodiment, the step (P1) can be performed in the same manner as the method described in the section of [cleaning step (P1)] of (second aspect: method of cleaning substrate) described above.

Examples of the optional steps include a hard mask layer etching step, a wiring layer dry-etching step, and a contact etching step, before the step (P1). Further, examples of the optional steps include known steps performed in a case of manufacturing a semiconductor element, such as formation steps of capacitor formation, channel formation, High-K/metal gate formation, each structure such as a metal wiring, a gate structure, a source structure, a drain structure, an insulating layer, a ferromagnetic layer, or a nonmagnetic layer (such as layer formation, etching other than the above-described etching treatment, chemical-mechanical polishing, transformation), a resist film forming step, a light exposure step, a development step, a heat treatment step, and an inspection step.

Since the method of manufacturing a semiconductor element of the present embodiment described above includes a step (P1) of cleaning a substrate to which etching residues (titanium component-containing residues) including a titanium component are adhered, using the cleaning liquid according to the first aspect, the etching residues can be satisfactorily removed while damage to the metal wiring is suppressed. In this manner, the electrical characteristics of a semiconductor element to be manufactured can be improved.

### EXAMPLES

Hereinafter, the present invention will be described in more detail based on examples, but the present invention is not limited to these examples.

Components used in examples and comparative examples are shown below.

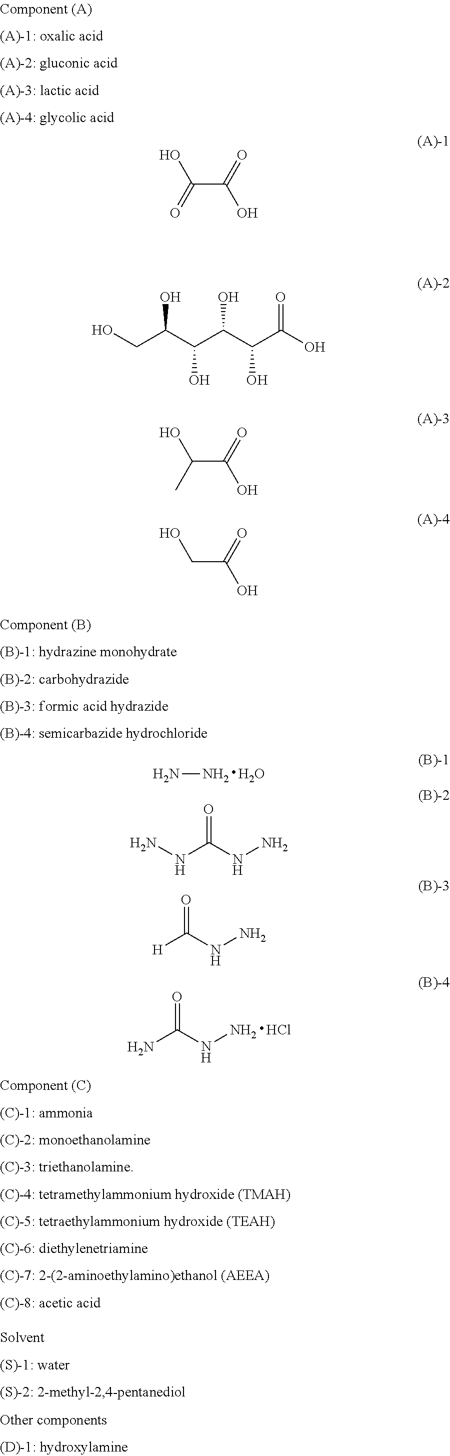

### Preparation of Cleaning Liquid

### Comparative Examples 1 to 7, Examples 1 to 36, and Reference Example 1

Each component listed in Tables 1 to 4 was used to prepare a cleaning liquid of each example.

In Tables 1 to 4, each abbreviation has the meaning described above. The numerical values in the brackets denote the amount of each component in the cleaning liquid, and indicate the proportion (% by mass) of the content mass of each component in the total mass (100% by mass in total) of the cleaning liquid.

### pH of Cleaning Liquid

The pH of the cleaning liquid was measured using a pH meter (portable pH meter D-73S, manufactured by Horiba, Ltd.) under a temperature condition of 23° C. The results are listed in the columns of “pH (23° C.)” in Tables 1 to 4.

### Evaluation

In the cleaning liquids of each example, the removal properties for titanium component-containing residues after being subjected to dry etching were evaluated using the etching rates described below as an index.

### Measurement of Etching Rate

A substrate obtained by forming a titanium nitride (TiN) film having a film thickness of 50 nm on a 12-inch silicon substrate using a PVD method was used as the substrate.

The substrate on which the film had been formed was cut into a size of 2 cm×2 cm to produce a wafer coupon.

100 mL of the cleaning liquid of each example was put into a beaker having a volume of 200 mL and heated to a treatment temperature of 60° C., and the cut wafer coupon was dipped in the cleaning liquid. The temperature of the cleaning liquid was continuously increased to 60° C. while the wafer coupon was dipped in the cleaning liquid. The wafer coupon was taken out from the cleaning liquid 3 hours after the dipping, cleaned with water at room temperature for 30 seconds, and dried by blowing nitrogen.

The film thicknesses of the wafer coupon before and after the dipping in the cleaning liquid were measured.

The film thicknesses of the wafer coupon including a TiN film were measured using an X-ray fluorescence spectrometer (ZSX Primus IV, Rigaku Corporation).

Further, the etching rate was calculated from the change in the film thickness of the TiN film before and after the cleaning treatment.

### Evaluation of Removal Properties for Titanium Component-Containing Residues

The removal properties for the titanium component-containing residues were evaluated according to the following evaluation criteria using the etching rates of the cleaning liquid with respect to the TiN film as an index. The results are listed in Tables 1 to 4.

The removal properties for the titanium component-containing residues are more excellent as the value of the etching rate increases.

### Evaluation Criteria of Removal Properties for Titanium Component-Containing Residues

A: The etching rate of the cleaning liquid with respect to the TiN film was greater than 0.5×10⁻¹⁰ m/min.

B: The etching rate thereof was greater than 0.25×10⁻¹⁰ m/min and 0.5×10⁻¹⁰ m/min or less.

C: The etching rate thereof was greater than 0.15×10⁻¹⁰ m/min and 0.25×10⁻¹⁰ m/min or less.

D: The etching rate thereof was 0.15×10⁻¹⁰ m/min or less.

TABLE 1

| | | | | | | Treatment | Removal |
|---|---|---|---|---|---|---|---|
| | Composition of cleaning liquid/mass % | | | | | temper- | properties |
| | Component | Component | Component | Component | pH | ature | for |
| | (A) | (B) | (C) | (S) | (23° C.) | [° C.] | titanium |
| Comparative | (A)-1 | — | — | (S)-1 | 1.0 | 60 | D |
| Example 1 | [6.3] | | | [remaining | | | |
| | | | | amount] | | | |
| Comparative | (A)-3 | — | — | (S)-1 | 2.0 | 60 | D |
| Example 2 | [9.0] | | | [remaining | | | |
| | | | | amount] | | | |
| Comparative | — | — | (C)-1 | (S)-1 | 12.0 | 60 | D |
| Example 3 | | | [2.0] | [remaining | | | |
| | | | | amount] | | | |
| Comparative | — | (B)-1 | — | (S)-1 | 11.0 | 60 | D |
| Example 4 | | [15] | | [remaining | | | |
| | | | | amount] | | | |
| Comparative | (A)-1 | — | (C)-1 | (S)-1 | 8.3 | 60 | D |
| Example 5 | [6.3 | | [2.0] | [remaining | | | |
| | | | | amount] | | | |
| Comparative | — | (B)-4 | (C)-1 | (S)-1 | 10.0 | 60 | D |
| Example 6 | | [5.5 | [2.5] | [remaining | | | |
| | | | | amount] | | | |
| Comparative | (A)-2 | — | (C)-2 | (S)-1 | 12.0 | 60 | D |
| Example 7 | [22.0] | | [48.5] | [remaining | | | |
| | | | (C)-3 | amount] | | | |
| | | | [22.0] | | | | |
| Example 1 | (A)-1 | (B)-1 | (C)-1 | (S)-1 | 8.0 | 60 | A |
| | [6.3] | [5] | [1.0] | [remaining | | | |
| | | | | amount] | | | |
| Example 2 | (A)-1 | (B)-2 | (C)-1 | (S)-1 | 9.0 | 60 | A |
| | [6.3] | [9] | [5.0] | [remaining | | | |
| | | | | amount] | | | |
| Example 3 | (A)-1 | (B)-3 | (C)-1 | (S)-1 | 9.0 | 60 | A |
| | [6.3] | [6] | [5.0] | [remaining | | | |
| | | | | amount] | | | |
| Example 4 | (A)-1 | (B)-4 | (C)-1 | (S)-1 | 9.0 | 60 | A |
| | [6.3] | [5.5] | [7.0] | [remaining | | | |
| | | | | amount] | | | |
| Example 5 | (A)-3 | (B)-1 | (C)-1 | (S)-1 | 8.0 | 60 | B |
| | [4.5] | [5] | [1.5] | [remaining | | | |
| | | | | amount] | | | |
| Example 6 | (A)-4 | (B)-1 | (C)-1 | (S)-1 | 8.0 | 60 | B |
| | [3.8] | [5] | [1.5] | [remaining | | | |
| | | | | amount] | | | |
| Example 7 | (A)-3 | (B)-4 | (C)-1 | (S)-1 | 10.0 | 60 | A |
| | [4.5] | [5.5 | [7.0] | [remaining | | | |
| Example 8 | (A)-4 | (B)-4 | (C)-1 | (S)-1 | 10.0 | 60 | A |
| | [3.8] | [5.5] | [7.0] | [remaining | | | |
| | | | | amount] | | | |
| Example 9 | (A)-1 | (B)-1 | (C)-4 | (S)-1 | 8.0 | 60 | A |
| | [6.3] | [5.0] | [0.7] | [remaining | | | |
| | | | | amount] | | | |
| Example 10 | (A)-1 | (B)-1 | (C)-2 | (S)-1 | 8.0 | 60 | A |
| | [6.3] | [5.0] | [3.0] | [remaining | | | |
| | | | | amount] | | | |

TABLE 2

| | | | | | | | Removal |
|---|---|---|---|---|---|---|---|
| | | | | | | | properties |
| | | | | | | | for |
| | | | | | | Treat- | titanium |
| | Composition of cleaning liquid/mass % | | | | | ment | component- |
| | Component | Component | Component | Component | pH | temper- | containing |
| | (A) | (B) | (C) | (S) | (23° C.) | ature | residues |
| Example 11 | (A)-1 | (B)-1 | (C)-5 | (S)-1 | 8.0 | 60 | A |
| | [6.3] | [5.0] | [1.0] | [remaining | | | |
| | | | | amount] | | | |
| Example 12 | (A)-1 | (B)-1 | (C)-6 | (S)-1 | 8.0 | 60 | B |
| | [6.3] | [5.0] | [3.0] | [remaining | | | |
| | | | | amount] | | | |
| Example 13 | (A)-1 | (B)-1 | (C)-7 | (S)-1 | 8.0 | 60 | B |
| | [6.3] | [5.0] | [3.0] | [remaining | | | |
| | | | | amount] | | | |
| Example 14 | (A)-1 | (B)-1 | — | (S)-1 | 7.0 | 60 | B |
| | [6.3] | [5.0] | | [remaining | | | |
| | | | | amount] | | | |
| Example 15 | (A)-1 | (B)-1 | (C)-1 | (S)-1 | 9.0 | 60 | B |
| | [6.3] | [5.0] | [2.0] | [remaining | | | |
| | | | | amount] | | | |
| Example 16 | (A)-1 | (B)-1 | (C)-8 | (S)-1 | 5.0 | 60 | B |
| | [6.3] | [5.0] | [1.0] | [remaining | | | |
| | | | | amount] | | | |
| Example 17 | (A)-1 | (B)-1 | (C)-8 | (S)-1 | 3.0 | 60 | B |
| | [6.3] | [5.0] | [2.0] | [remaining | | | |
| | | | | amount] | | | |
| Example 18 | (A)-1 | (B)-2 | (C)-1 | (S)-1 | 8.0 | 60 | B |
| | [6.3] | [9.0] | [4.0] | [remaining | | | |
| | | | | amount] | | | |
| Example 19 | (A)-1 | (B)-2 | (C)-1 | (S)-1 | 6.0 | 60 | B |
| | [6.3] | [9.0] | [3.0] | [remaining | | | |
| | | | | amount] | | | |
| Example 20 | (A)-1 | (B)-4 | (C)-4 | (S)-1 | 12.0 | 60 | B |
| | [6.3] | [5.5] | [7.0] | [remaining | | | |
| | | | | amount] | | | |
| Example 21 | (A)-1 | (B)-4 | (C)-1 | (S)-1 | 8.0 | 60 | B |
| | [6.3] | [5.5] | [6.0] | [remaining | | | |
| | | | | amount] | | | |
| Example 22 | (A)-1 | (B)-4 | (C)-1 | (S)-1 | 5.0 | 60 | B |
| | [6.3] | [5.5] | [5.0] | [remaining | | | |
| | | | | amount] | | | |
| Example 23 | (A)-1 | (B)-4 | — | (S)-1 | 0.5 | 60 | C |
| | [6.3] | [5.5] | | [remaining | | | |
| | | | | amount] | | | |
| Example 24 | (A)-3 | (B)-4 | (C)-1 | (S)-1 | 10.0 | 60 | A |
| | [30] | [5.5] | [15.0] | [remaining | | | |
| | | | | amount] | | | |
| Example 25 | (A)-3 | (B)-4 | (C)-1 | (S)-1 | 10.0 | 60 | A |
| | [15.0] | [5.5] | [10.0] | [remaining | | | |
| | | | | amount] | | | |

TABLE 3

| | | | | | | | Removal |
|---|---|---|---|---|---|---|---|
| | | | | | | | properties |
| | | | | | | | for |
| | | | | | | Treatment | titanium |
| | Composition of cleaning liquid/mass % | | | | | temper- | component- |
| | Component | Component | Component | Component | pH | ature | containing |
| | (A) | (B) | (C) | (S) | (23° C.) | [° C.] | residues |
| Example 26 | (A)-1 | (B)-4 | (C)-1 | (S)-1 | 10.0 | 60 | A |
| | [1.0] | [5.5] | [5.0] | [remaining | | | |
| | | | | amount] | | | |
| Example 27 | (A)-1 | (B)-4 | (C)-1 | (S)-1 | 10.0 | 60 | A |
| | [0.5] | [5.5] | [4.5] | [remaining | | | |
| | | | | amount] | | | |
| Example 28 | (A)-1 | (B)-4 | (C)-1 | (S)-1 | 10.0 | 60 | B |
| | [0.05] | [5.5] | [4.0] | [remaining | | | |
| | | | | amount] | | | |
| Example 29 | (A)-1 | (B)-4 | (C)-1 | (S)-1 | 10.0 | 60 | A |
| | [6.3] | [30] | [20.0] | [remaining | | | |
| | | | | amount] | | | |
| Example 30 | (A)-1 | (B)-4 | (C)-1 | (S)-1 | 10.0 | 60 | A |
| | [6.3] | [10.0] | [10.0] | [remaining | | | |
| | | | | amount] | | | |
| Example 31 | (A)-1 | (B)-4 | (C)-1 | (S)-1 | 10.0 | 60 | A |
| | [6.3] | [1.0] | [5.0] | [remaining | | | |
| | | | | amount] | | | |
| Example 32 | (A)-1 | (B)-4 | (C)-1 | (S)-1 | 10.0 | 60 | A |
| | [6.3] | [0.5] | [4.5] | [remaining | | | |
| | | | | amount] | | | |
| Example 33 | (A)-1 | (B)-4 | (C)-1 | (S)-1 | 10.0 | 60 | C |
| | [6.3] | [0.05] | [4.0 | [remaining | | | |
| | | | | amount] | | | |
| Example 34 | (A)-1 | (B)-1 | — | (S)-2 | 8.0 | 60 | A |
| | [5] | [5] | | [75] | | | |
| | | | | (S)-1 | | | |
| | | | | [remaining | | | |
| | | | | amount] | | | |
| Example 35 | (A)-1 | (B)-1 | — | (S)-2 | 8.0 | 60 | A |
| | [5] | [5] | | [50] | | | |
| | | | | (S)-1 | | | |
| | | | | [remaining | | | |
| | | | | amount] | | | |
| Example 36 | (A)-1 | (B)-1 | — | (S)-2 | 8.0 | 60 | A |
| | [5] | [5] | | [25] | | | |
| | | | | (S)-1 | | | |
| | | | | [remaining | | | |
| | | | | amount] | | | |

TABLE 4

| | | | | | Removal |
|---|---|---|---|---|---|
| | | | | | properties for |
| | | | | | titanium |
| | Composition of cleaning | | | Treatment | component- |
| | liquid/mass % | | pH | temperature | containing |
| | Component (D) | Component (S) | (23° C.) | [° C.] | residues |
| Reference | (D)-1 | (S)-1 | 9.8 | 60 | A |
| Example 1 | [1.0] | [remaining | | | |
| | | amount] | | | |

As shown the results listed in Tables 1 to 4, it was confirmed that the cleaning liquids of Examples 1 to 36 to which the present invention was applied had satisfactory removal properties for the titanium component-containing residues as compared with the cleaning liquids of Comparative Examples 2 to 7 which were outside the scope of the present invention. The cleaning liquids of Examples 1 to 36 exhibited cleaning properties with respect to the titanium component-containing residues, similar to the cleaning properties of the cleaning liquid containing hydroxylamine in Reference Example 1. Since the cleaning liquids of Examples 1 to 36 did not contain hydroxylamine, the safety thereof was higher than the safety of the cleaning liquid of Reference Example 1. As shown in the results listed in Tables 1 to 4, it was confirmed that a cleaning liquid having excellent removal properties for titanium component-containing residues was obtained by using a combination of the component (A) and the component (B) without using hydroxylamine.

Hereinbefore, the preferable examples of the present invention have been described, but the present invention is not limited thereto. Additions, omissions, substitutions, and other modifications can be made without departing from the scope of the present invention. The present invention is not limited by the above description, but only by the appended claims.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

10: Substrate
20: Metal wiring layer
30: Etching stop layer
40: Interlayer insulating film
50: Hard mask layer (HM layer)
60: Dry etching residue
100: Element

What is claimed is:

1. A cleaning liquid for removing an etching residue containing a titanium component, the cleaning liquid comprising:
a compound (A) represented by General Formula (a1); and
a compound (B) represented by General Formula (b1), 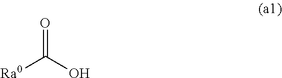
wherein Ra⁰ represents a monovalent organic group containing a hydroxy group or a carboxy group, or a hydrogen atom, 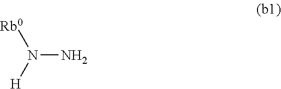
wherein Rb⁰ represents a monovalent organic group or a hydrogen atom.

2. The cleaning liquid according to claim 1, wherein Ra⁰ in General Formula (a1) represents a group having a carbon atom to which a hydroxy group is bonded at an α-position of a carboxy group in General Formula (a1).

3. The cleaning liquid according to claim 2, wherein Ra⁰ in General Formula (a1) represents a hydroxyalkyl group having 1 to 6 carbon atoms, a carboxyalkyl group having 1 to 6 carbon atoms, or a carboxy group.

4. The cleaning liquid according to claim 1, wherein Rb⁰ in General Formula (b1) represents a group having a carbon atom to which an oxo group is bonded at an α-position of a hydrazino group in General Formula (b1).

5. The cleaning liquid according to claim 4,
wherein the compound (B) is hydrazine or a compound represented by General Formula (b1-1), 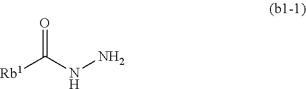
wherein Rb¹ represents a monovalent organic group, a hydrogen atom, an amino group, or a hydrazino group.

6. The cleaning liquid according to claim 1, wherein an amount of the compound (A) is in a range of 0.05% to 30% by mass with respect to a total mass of the cleaning liquid.

7. The cleaning liquid according to claim 1, wherein an amount of the compound (B) is in a range of 0.05% to 30% by mass with respect to a total mass of the cleaning liquid.

8. The cleaning liquid according to claim 1, wherein a mass ratio of an amount of the compound (A) to an amount of the compound (B) is in a range of 0.0001 to 200.

9. The cleaning liquid according to claim 1, wherein the cleaning liquid is used for cleaning a substrate that includes a titanium component-containing layer and has been subjected to dry etching.

10. The cleaning liquid according to claim 1, wherein the cleaning liquid is used for cleaning a substrate that has been subjected to dry etching using a titanium component-containing hard mask by a wiring process.

11. A method of cleaning a substrate, comprising cleaning a substrate to which an etching residue including a titanium component is adhered, using the cleaning liquid according to claim 1.

12. The method of cleaning a substrate according to claim 11, wherein the substrate is cleaned using the cleaning liquid at 10° C. to 80° C.

13. The method of cleaning a substrate according to claim 11, wherein the substrate includes a titanium component-containing layer and has been subjected to dry etching.

14. The method of cleaning a substrate according to claim 11, wherein the substrate has been subjected to dry etching using a titanium component-containing hard mask by a wiring process.

15. A method of manufacturing a semiconductor element, the method comprising cleaning a substrate to which an etching residue including a titanium component is adhered, using the cleaning liquid according to claim 1.
